(19) United States
(12) Patent Application Publication
(10) Pub. No.: US 2021/0392764 A1
(43) Pub. Date: Dec. 16, 2021

(54) DISPLAY APPARATUS

(71) Applicant: SAMSUNG ELECTRONICS CO., LTD., Suwon-si, (KR)

(72) Inventors: Gyeong Joong KIM, Suwon-si (KR); Pil Yong OH, Suwon-si (KR); Yong Soon LEE, Suwon-si (KR); Seung Sik TAK, Suwon-si (KR)

(73) Assignee: SAMSUNG ELECTRONICS CO., LTD., Suwon-si (KR)

(21) Appl. No.: 17/282,943

(22) PCT Filed: Sep. 30, 2019
(86) PCT No.: PCT/KR2019/012753

§ 371 Date: Apr. 5, 2021

(30) Foreign Application Priority Data
Oct. 5, 2018 (KR) 10-2018-0119202

(51) Int. Cl. H05K 5/02; H05K 5/00; G09F 9/33

(52) U.S. Cl. CPC H05K 5/0217; H01L 25/0753; G09F 9/33; H05K 5/0017

(57) ABSTRACT

Disclosed is a display apparatus including a configuration for adjusting step difference of printed circuit boards (PCBs) on which a micro light emitting diode (Micro LED) is mounted. The display apparatus may comprises: a printed circuit board (PCB) on which a plurality of light emitting diodes (LEDs) emitting light in a first direction are mounted; a frame configured to support the PCB in a second direction opposite to the first direction; a chassis coupled to the frame in the second direction; and an adjusting unit configured to finely adjust the PCB in the first direction or the second direction, wherein the adjusting unit includes: a height-adjustable screw configured to be inserted in the first direction; a first cam linearly moving in the first direction or the second direction by rotation of the height-adjustable screw; a second cam interlocking with the first cam so as to linearly move in a third direction that is perpendicular to the first direction and the second direction, or in a direction opposite.

### TECHNICAL FIELD

The disclosure relates to a display apparatus, and more particularly, to a display apparatus including a configuration for adjusting a step difference of printed circuit boards (PCBs) on which a micro light emitting diode (MicroLED) is mounted.

### BACKGROUND ART

An LED display apparatus using an LED has superior brightness and color characteristics than other types of display apparatuses (e.g., LCD type display apparatus), and thus is used for indoor/outdoor signboards, indoor/outdoor direction boards, electronic boards of stadiums, or indoor/outdoor backdrops.

Particularly, in the case of an LED display apparatus using a microLED, as the micrometer unit LED is mounted on the printed circuit board (PCB), the pixels constituting the pixels can be set in micrometer units and high contrast ratio and high resolution can be reproduced.

In addition, by using a light emitting device of a micrometer unit, it is arranged in a matrix form of M×N (M and N are natural numbers), so that it is easy to expand the size while maintaining high quality. As the demand for an LED display apparatus implemented in the form of an M×N matrix increases, the need for an LED display apparatus that is easy to move and install is increasing.

In the case of the PCB on which the microLED is mounted, the size of the PCB is limited, so a plurality of PCBs may be assembled into a single display apparatus. At this time, when the plurality of PCBs are assembled to have steps with different levels, the image quality of the display apparatus may be lowered.

### DISCLOSURE

### Technical Problem

According to embodiments of the disclosure, there is provided a display apparatus including an adjusting unit capable of easily adjusting a fine step difference occurring between a plurality of PCBs on which Micro LEDs are mounted.

In accordance with an aspect of the disclosure, a display apparatus includes a printed circuit board (PCB) on which a plurality of light emitting diodes (LEDs) emitting light in a first direction are mounted; a frame configured to support the PCB in a second direction opposite to the first direction; a chassis coupled to the frame in the second direction; and an adjusting unit configured to finely adjust the PCB in the first direction or the second direction, wherein the adjusting unit may include: a height-adjustable screw configured to be inserted in the first direction; a first cam linearly moving in the first direction or the second direction by rotation of the height-adjustable screw; a second cam interlocking with the first cam so as to linearly move in a third direction that is perpendicular to the first direction and the second direction, or in a direction opposite to the third direction; and a third cam interlocking with the second cam so as to linearly move in the first direction or the second direction, and configured to come in contact with the PCB.

The frame may include an insertion hole provided so that the adjusting unit is inserted into the frame, the insertion hole including a first opening formed in the first direction and a second opening formed in the second direction; and the third cam is provided to come contact with the PCB through the first opening.

The adjusting device may be provided to be coupled to the chassis through the second opening.

The adjusting device may further include a housing configured to cover the first, second, and third cams, and the housing may include a first surface including a first cutout portion through which the third cam passes, and a second surface disposed parallel to the first surface and including a second cutout portion through which the height-adjustable screw passes.

The second surface may be provided to be coupled to the chassis, and the chassis may include an adjustment hole formed at a position corresponding to the height-adjustable screw, and provided to expose the height-adjustable screw from an outside when the second surface is coupled the chassis.

The first cam may include a first cam surface configured to come in contact with the second cam, the second cam may include a second cam surface configured to come in contact with the first cam surface, and the first cam surface and the second cam surface may be provided to be inclined with respect to the first direction

The second cam may include a third cam surface configured to come in contact with the third cam, the third cam may include a fourth cam surface configured to come in contact with the third cam surface, and the third cam surface and the fourth cam surface may be provided to be inclined with respect to the third direction.

The second cam may be provided to move in the third direction by being pressed against the first cam surface.

The third cam may be provided to be translated in the first direction and the second direction by being pressed against the third cam surface.

The second cam may include a guide protrusion protruding from the third cam surface to prevent the fourth cam surface from being separated from the third cam surface; and the third cam may further include a guide rail into which the guide protrusion is inserted.

The adjusting device may further include a pressing member configured to press the third cam toward the second cam to prevent the fourth cam surface from being separated from the third cam surface

The adjusting device may further include an elastic member disposed between one inner surface of the housing and the second cam to press the second cam in a direction opposite to the third direction

The adjusting device may further include a screw fixing portion that limits movement of the height-adjustable screw in the first direction or the second direction.

The third cam may include a support surface configured to support the PCB; and the adjusting device may further include a first adhesive portion configured to bond the PCB to the support surface.

The frame may include a second adhesive portion configured to bond the frame to the PCB.

In accordance with an aspect of the disclosure, a display apparatus includes a printed circuit board (PCB) on which a plurality of light emitting diodes (LEDs) emitting light in a first direction are mounted; a frame configured to support the PCB in a second direction opposite to the first direction; a chassis coupled to the frame in the second direction; and an adjusting unit configured to finely adjust the PCB in the first direction or the second direction, wherein the frame may include an insertion hole provided so that the adjusting unit is inserted into the frame, the insertion hole including a first opening formed in the first direction and a second opening formed in the second direction, and the adjusting unit is provided to come in contact with the PCB through the first opening and is provided to come in contact with the chassis through the second opening.

The adjusting unit may include a height-adjustable screw configured to be inserted in the first direction to adjust a adjustment height of the adjusting unit; the chassis may include an adjustment hole formed at a position corresponding to the height-adjustable screw and provided to expose the height-adjustable screw from an outside when the adjusting unit is coupled to the chassis; and the adjusting unit may be provided to adjust the adjustment height through the height-adjustable screw at a rear side of the chassis.

The adjusting unit may include: a height-adjustable screw configured to be inserted in the first direction; a first cam configured to linearly move in the first direction or the second direction by rotation of the height-adjustable screw; a second cam interlocking with the first cam so as to linearly move in a third direction that is perpendicular to the first direction and the second direction, or in a direction opposite to the third direction; and a third cam interlocking with the second cam so as to linearly move in the first direction or the second direction, and configured to come in contact with the PCB.

The height-adjustable screw may include a thread having a pitch in the first direction and disposed to be inclined to the first direction; and the first cam, the second cam, and the third cam may be linked with the rotation of the height-adjustable screw to move the PCB by a distance smaller than the pitch of the thread.

In accordance with an aspect of the disclosure, a display apparatus includes: a printed circuit board (PCB) on which a plurality of light emitting diodes (LEDs) emitting light in a first direction are mounted; a frame configured to support the PCB in a second direction opposite to the first direction; a chassis coupled to the frame in the second direction; and an adjusting unit configured to finely adjust the PCB in the first direction or the second direction, wherein the adjusting unit may include: a height-adjustable screw including a thread configured to be inserted in the first direction and having a pitch in the first direction and disposed to be inclined to the first direction; and three cams linked with rotation of the height-adjustable screw to move the PCB by a distance smaller than the pitch of the thread.

### Advantageous Effects

As is apparent from the above, according to a concept of the disclosure, the adjusting unit is coupled between the chassis and the PCB on which the LED is mounted, and the adjusting device enables fine movement in the front and rear direction of the PCB through the plurality of cam members, and image quality of the display apparatus can be improved by adjusting the fine step difference that may occur between the plurality of PCBs.

### DESCRIPTION OF DRAWINGS

FIG. 1 is a perspective view illustrating a display apparatus according to an embodiment of the disclosure.

FIG. 2 is an exploded perspective view illustrating the display apparatus according to the embodiment of the disclosure.

FIG. 3 is a view illustrating a state in which a part of the display apparatus according to the embodiment is separated.

FIG. 4 is a view illustrating a state in which a part of the display apparatus according to the embodiment is separated.

FIG. 5 is a cross-sectional view illustrating a part of the display apparatus according to the embodiment of the disclosure.

FIG. 6 is a perspective view illustrating an adjusting unit of the display apparatus according to the embodiment of the disclosure.

FIG. 7 is a cross-sectional side view illustrating the adjusting unit of the display apparatus according to the embodiment of the disclosure.

FIG. 8 is a side cross-sectional view illustrating the adjusting unit of the display apparatus according to the embodiment of the disclosure in an adjusted state.

FIG. 9 is a cross-sectional side view illustrating an adjusting unit of a display apparatus according to another embodiment of the disclosure.

FIG. 10 is a side cross-sectional view illustrating an adjusted state of the adjusting unit of the display apparatus according to another embodiment of the disclosure.

### MODES OF THE INVENTION

Embodiments and features as described and illustrated in the disclosure are only examples, and various modifications thereof may also fall within the scope of the disclosure.

Throughout the drawings, like reference numerals refer to like parts or components.

The terminology used herein is for the purpose of describing particular embodiments only and is not intended to limit the disclosure. It is to be understood that the singular forms “a,” “an,” and “the” include plural references unless the context clearly dictates otherwise. It will be further understood that the terms “include”, “comprise” and/or “have” when used in this specification, specify the presence of stated features, integers, steps, operations, elements, and/or components, but do not preclude the presence or addition of one or more other features, integers, steps, operations, elements, components, and/or groups thereof.

The terms including ordinal numbers like “first” and “second” may be used to explain various components, but the components are not limited by the terms. The terms are only for the purpose of distinguishing a component from another. Thus, a first element, component, region, layer or section discussed below could be termed a second element, component, region, layer or section without departing from the teachings of the disclosure. The term “and/or,” includes any and all combinations of one or more of the associated listed items.

Descriptions shall be understood as to include any and all combinations of one or more of the associated listed items when the items are described by using the conjunctive term “^{˜}and/or^{˜},” or the like. A content may be displayed on a display apparatus. The content may be received from a control device configured to perform control in connection with the display apparatus and/or another display apparatus connected to the display apparatus. In addition, the content may be received from an external server. For example, the content may be a video file or an audio file played in a video player, a music file played in a music player, a photo file displayed on a photo gallery, and a web page file or a text file displayed on a web browser. In addition, the content may include broadcasts received.

Hereinafter, embodiments of the disclosure will be described in detail with reference to the accompanying drawings.

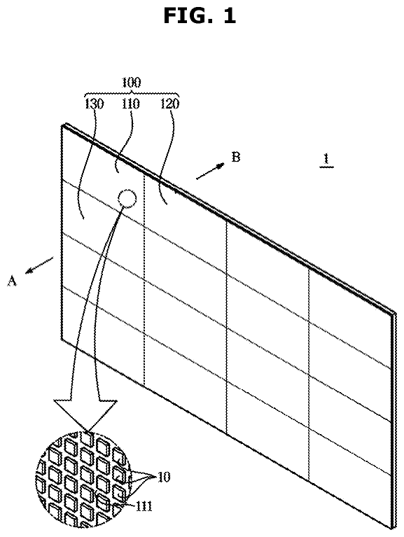

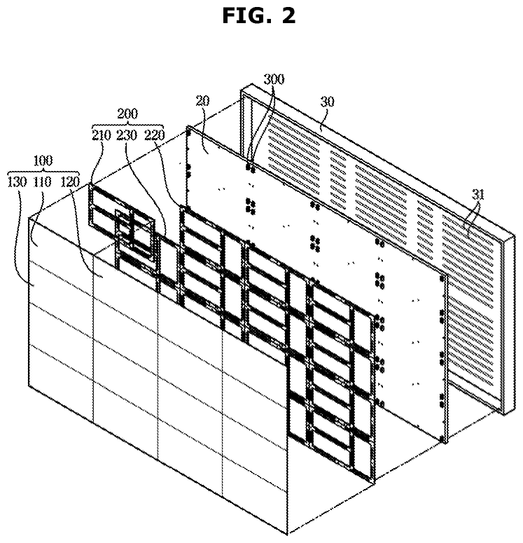

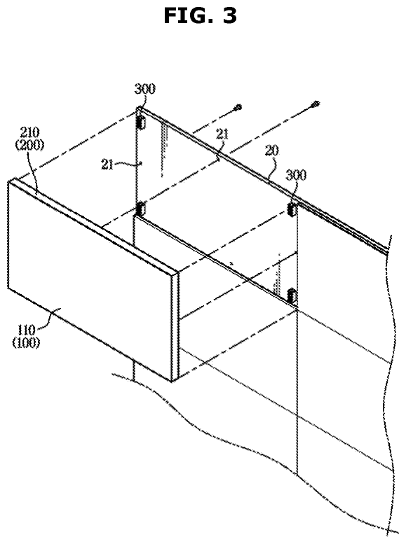

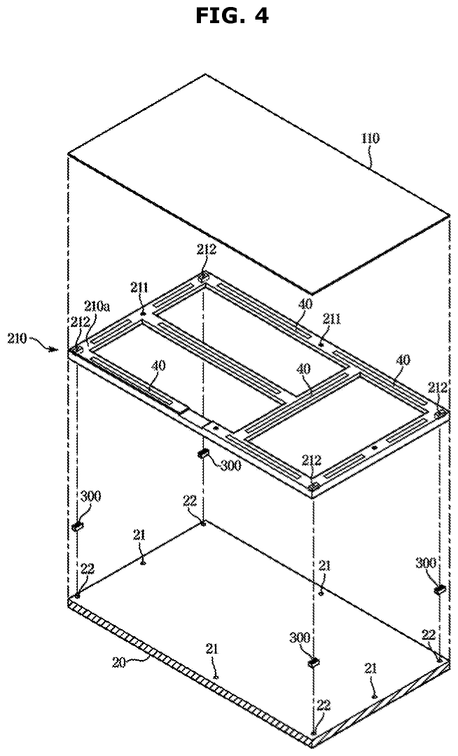

FIG. 1 is a perspective view illustrating a display apparatus according to an embodiment of the disclosure, FIG. 2 is an exploded perspective view illustrating the display apparatus according to the embodiment of the disclosure, FIG. 3 is a view illustrating a state in which a part of the display apparatus according to the embodiment is separated, and FIG. 4 is a view illustrating a state in which a part of the display apparatus according to the embodiment is separated.

The display apparatus 1 may include a plurality of printed circuit boards(PCBs) 100 on which a plurality of LEDs 10 are respectively mounted. The plurality of PCBs 100 may include a first PCB 110 and a second PCB 120 and a third PCB 130, and the plurality of PCBs 100 may be arranged in various ways according to the size of the display apparatus 1.

The plurality of LEDs 10 may be mounted on each of the first PCB 110, the second PCB 120, and the third PCB 130. Since each of the PCBs 110, 120 and 130 is implemented in the same form, the following description will be made only on the first PCB 110 for the sake of convenience. In addition, since the plurality of PCBs 100 are all implemented in the same form, the plurality of PCBs 100 will be described with the first PCB 110 as an example for the sake of convenience.

The first PCB 110 may include a mounting surface 111 on which a plurality of LEDs 10 are mounted. The mounting surface 111 is disposed to face in a first direction A, which is a forward direction of the display apparatus 1, and the plurality of LEDs 10 mounted on the mounting surface 111 may emit light in the first direction A.

The plurality of LEDs 10 may be implemented by arranging LEDs emitting red, green, and blue light in the form of a matrix.

The plurality of LEDs 10 may include a red LED (not shown), a green LED (not shown), and a blue LED (not shown), packaged in the form of a matrix for a single pixel. A LED, a green LED, and a blue LED constituting one pixel may be called a sub pixel. A pixel may be implemented with LEDs emitting light in white color and color filters that filter white color into various colors.

The plurality of LEDs 10 may implement a single pixel with sub-pixels including a red LED, a green LED, and a blue LED, and may be repeatedly arranged.

The plurality of LEDs 10 may be mounted on the mounting surface 111 in the form of a matrix (e.g., M×N, where M and N are natural numbers). The matrix may have the same arrays (e.g., M=N, where M and N are natural numbers, such as a 16×16 array, a 24×24 array, and the like). Alternatively, the matrix may have different arrays (e.g., M≠N, where M and N are natural numbers).

The display apparatus 1 may implement a screen using the plurality of LEDs 10 mounted on each of the plurality of PCBs 100, and display a content by driving the plurality of LEDs 10.

The display apparatus 1 may include a plurality of frames 200 supporting the plurality of PCBs 100. The plurality of frames 200 may support the plurality of PCBs 100 in a second direction B opposite to the first direction.

The plurality of frames 200 may include a first frame 210 corresponding to the first PCB 110, a second frame 220 corresponding to the second PCB 120, and a third frame 330 corresponding to the third PCB 130, and may be arranged in various ways according to the size of the display apparatus 1 and the number of the plurality of PCBs 100.

The first frame 210, the second frame 220, and the third frame 230 may support the PCBs 110, 120, and 130, respectively. Since each of the frame 210, 220, and 230 is all implemented in the same form, for the sake of convenience the following description will be made only on the first frame 210 corresponding to the first PCB 110. In addition, since the plurality of frames are implemented in the same form, for convenience of description, the plurality of frames 200 will be described with the first frame 210 as an example.

The first frame 210 may include a front surface 210a supporting an opposite surface 112 of the first PCB 110. The front surface 210a is provided to come in contact with the opposite surface 112 of the first PCB 110, and may support the first PCB 110.

Particularly, an adhesive layer 40 is disposed on the front surface 210a, and the adhesive layer 40 bonds the front surface 210a and the opposite surface 112, which makes the front surface 210a to support the opposite side 112 of the first PCB.

The display apparatus 1 may include an electronic unit(not shown) which is electrically connected to the first PCB 110 and transmits an electrical signal to the first PCB 110 in order to display an image on the first PCB 110. The electronic unit (not shown) may be disposed in the inner space of the first frame 210.

The first PCB 110 is coupled to the first frame 210, and the coupled first PCB 110 and the first frame 210 may be coupled with a chassis 20 to be described later.

The display apparatus 1 may include a chassis 20 that is coupled with the first frame 210 in the second direction B. The chassis 20 may stably support the first PCB 110 and the first frame 210.

Particularly, when the plurality of LEDs 10 are formed of microLED, the plurality of PCBs 100 may be formed of a glass material in order to transfer the microLED. At this time, in the case of the plurality of PCBs 100 including a glass material compared to a conventional PCB, when directly supported on the chassis 20, a problem with respect to strength may occur.

The conventional PCB on which LEDs are mounted may be formed of an epoxy resin, a phenol resin, or a composite resin, in this case, in order to couple the conventional PCB to a chassis, a component, such as a stud, is coupled to the PCB using soldering, and the PCB is coupled to the chassis through the stud coupled to the PCB.

At this time, when the PCB is formed of glass, high temperature heat generated during the soldering of the stud may cause deformation of the PCB and cause difficulty in soldering the stud at a correct position.

When the plurality of PCBs are installed in the chassis with the PCBs partially deformed or the studs positioned at incorrect positions, the plurality of PCBs may have unintentional gaps and height differences therebetween, which may degrade the reliability of the display screen.

In addition, when the plurality of PCBs 100 are formed of glass, the durability of the PCB is lowered when compared to the conventional PCB, and thus the plurality of PCBs 100 having a thin panel shape may be subject to warpage in a process of being arranged on the chassis 20.

However, as in the embodiment of the disclosure, the plurality of PCBs 100 are coupled with the chassis 20 in a state of being coupled to the plurality of frames 200, respectively, and the reliability of the strength of the plurality of PCBs 100 may be improved.

The first frame 210 may be coupled to the chassis 20 in various ways, such as screw coupling, magnet coupling, and latch coupling. According to an embodiment of the disclosure, the first frame 210 may include a first connection hole 211, and the chassis 20 may include a second connection hole 21 provided to be screwed with the first connection hole 211. Accordingly, the first frame 210 and the chassis 20 may be screw-coupled.

As described above, by combining the plurality of PCBs 100 to the chassis 20 through the plurality of frames 200, the plurality of PCBs 100 may be easily assembled to the chassis 20. Therefore, when any one of the plurality of PCBs 100 needs to be replaced due to damage, and the like, any one of the plurality of PCBs may be easily replaced by screwing off the frame 200 and the chassis 20 corresponding to any one of the plurality of PCBs.

The display apparatus 1 may include a cover member 30 covering a rear surface 20b of the chassis 20. The cover member 30 may include a plurality of outlets 31 provided to discharge heat generated inside the display apparatus 1.

Heat generated from the plurality of PCBs 100 may be continuously transferred to the chassis 20 through the plurality of frames 200. Heat conducted to the chassis 20 may be radiated to the outside through the outlets 31 of the cover member 30.

The cover member 30 may be provided to cover the rear surface 20b of the chassis 20 and cover the side surfaces of the plurality of frames 200 as well as the side surfaces of the chassis 20.

The display apparatus 1 may include an adjusting unit 300 provided to adjust a step difference which may be formed between each PCB 100 when the plurality of PCBs 100 are coupled to the chassis 20 through the plurality of frames 200.

The adjusting unit 300 may be provided in plural so as to correspond to two or more of each PCB 100. According to an embodiment of the disclosure, four adjusting units 300 may be provided to adjust the step difference of the single PCB 100.

Since all of the plurality of adjusting units 300 are formed identically, only one adjusting unit 300 will be described.

As described above, the plurality of PCBs 100 may be coupled to the chassis 20 through the plurality of frames 200. At this time, due to an installation problem, the first PCB 110 and the second PCB 120 may not be disposed in the same height in the first direction A.

At this time, when a height difference (step difference) occurs between the first PCB 110 and the second PCB 120, disadvantages that a boundary area between the first PCB 110 and the second PCB 120 is visible occur, and thus a problem that the reliability of image quality of the display apparatus 1 is deteriorated may occur.

In other words, the step difference between each PCB 100 should be designed to be less than a predetermined micrometer, but in the process of installing each PCB 100, the step difference of each PCB 100 may occur by the predetermined micrometer or more, and thus there may be a problem of deteriorating image quality.

Particularly, as described above, in particular, when the plurality of LEDs 10 are formed of microLEDs, depending on problems such as durability of the PCB, it may be formed in a smaller size than a conventional PCB, accordingly, a larger number of PCBs may be coupled with the chassis.

Therefore, as a large number of PCBs are coupled to the chassis, the probability of occurrence of a step difference between each PCB increases, and accordingly, there may be a greater concern that the image quality of the display apparatus is deteriorated.

In the related art, a display apparatus included a height-adjustable screw between a PCB and a chassis in order to adjust such a step difference between such PCBs, and so a height of each PCB could be adjusted by adjusting the height-adjustable screw.

However, in the case of the display apparatus in which a plurality of LEDs are formed of microLEDs or having high resolution and high definition, since a pitch between the plurality of LEDs is finely formed, the step difference of the PCB needs to be also finely adjusted to maintain the image quality of the display apparatus.

At this time, in the case of the height-adjustable screw, depending on a diameter of the height-adjustable screw and a pitch between threads of the height-adjustable screw, a length capable to adjust a height of the PCB per one rotation of the height-adjustable screw, is determined, and it is difficult to form the diameter of the height-adjustable screw or the pitch of the thread into a fine length, so it may occur a problem that the fine step difference of a PCB cannot be adjusted through the height-adjustable screw may occur.

To avoid the problem like this, a display apparatus 1 according to an embodiment of the disclosure may include the adjusting unit 300 capable of adjusting a step difference of each PCB 100.

Hereinafter, the adjusting unit 300 will be described in detail.

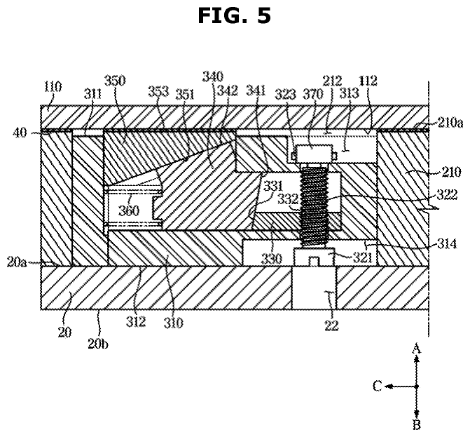

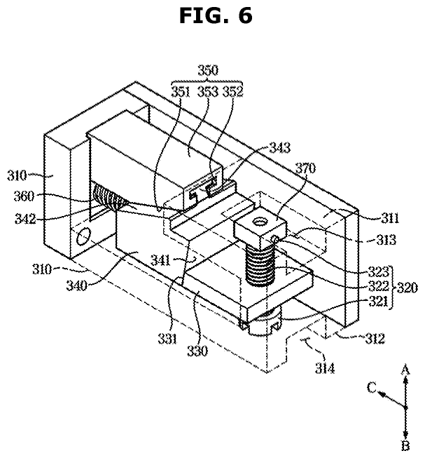

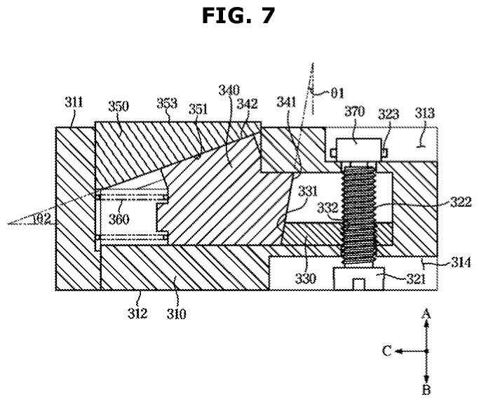

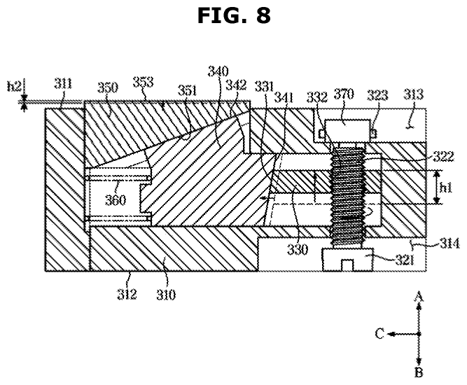

FIG. 4 is a view illustrating a state in which a part of the display apparatus according to the embodiment is separated, FIG. 5 is a cross-sectional view illustrating a part of the display apparatus according to the embodiment of the disclosure, FIG. 6 is a perspective view illustrating an adjusting unit of the display apparatus according to the embodiment of the disclosure, FIG. 7 is a cross-sectional side view illustrating the adjusting unit of the display apparatus according to the embodiment of the disclosure, and FIG. 8 is a side cross-sectional view illustrating the adjusting unit of the display apparatus according to the embodiment of the disclosure in an adjusted state.

As shown in FIGS. 4 and 5, the adjusting unit 300 may be inserted into an insertion hole 212 provided in the first frame 210.

The insertion hole 212 may include a first opening formed in the first direction A and a second opening formed in the second direction B.

The adjusting unit 300 may come in contact with the opposite surface 112 of the first PCB 110 through the first opening, and it may be coupled to a connection surface 20a of the chassis 20 through the second opening.

The adjusting unit 300 may be inserted into the insertion hole 212 in a state of being coupled to the connection surface 20a of the chassis 20 when the first frame 210 is coupled with the chassis 20.

The adjusting unit 300 may include a housing 310, a height-adjustable screw 320 configured to be inserted in the first direction A, a first cam 330 that linearly moves in the first direction A or in the second direction B by rotation of the height-adjustable screw 320, a second cam 340 that is interlocking with the first cam and linearly moves in a third direction C, which is perpendicular to the first direction A and the second direction B, or in a direction opposite to the third direction C, and a third cam 350 that is interlocking with the second cam 340 and linearly moves in the first direction A or in the second direction B, come in contact with the first PCB 110.

The housing 310 may be formed of a plurality of pieces as shown in the drawing, but is not limited thereto and may be formed of a single configuration.

The housing 310 may include a first surface 311 facing the opposite surface 112 of the first PCB 110 and a second surface 312 disposed parallel to the first surface 311 and coupled to the connection surface 21 of the chassis 20.

The housing 310 may include a first cutout portion 313 disposed on the first surface 311 and on which a screw fixing portion 370 to be described later is disposed, and a second cutout portion 314 disposed on the second surface 312 and through which the height-adjustable screw 320 passes.

The height-adjustable screw 320 may be inserted into the housing 310 through the second cutout portion 314.

The height-adjustable screw 320 may include a rotating portion 321 provided to allow a user to rotate the height-adjustable screw 320 through a driver or the like, a thread 322, and a fixing pin 323 fixed to the screw fixing portion 370.

The height-adjustable screw 320 may be inserted into the housing 310 in the first direction A. A rotation part 321 may be formed at the rear end of the height adjustment screw 320 in the first direction A, and a fixing pin 323 may be inserted at the front end.

The screw fixing portion 370 may propose to be moved in the first direction A or in the second direction B by the thread 322 when the height-adjustable screw 320 is rotated.

The screw fixing portion 370 may be coupled with the height-adjustable screw 320 by the fixing pin 323. When the height-adjustable screw 320 is rotated, the screw fixing portion 370 may be rotated in one direction or in the opposite direction by being linked with it.

The screw fixing portion 370 may be disposed inside the first cutout portion 311. The first cutout portion 311 may include a restraining portion(not shown) for restraining the screw fixing portion 370 so that the screw fixing portion 370 is rotated in the third direction C without moving in the first direction A and the second direction B.

Accordingly, the screw fixing portion 370 may be rotated inside the first cutout portion 311, and a linear motion may be limited. The height-adjustable screw 320 may be linked with the screw fixing portion 370 to allow rotational motion, and limit the translational motion in the first direction A and the second direction B.

The height-adjustable screw 320 may not move in the first direction A and the second direction B, but it may be rotated in the third direction C by the screw fixing portion 370.

The chassis 20 may include an adjustment hole 22 formed at a position corresponding to the height-adjustable screw 320 when the adjusting unit 300 is coupled to the connection surface 20a of the chassis 20.

Through the adjustment hole 22, the user may rotate the height-adjustable screw 320 through the rear surface 20b of the chassis 20.

The first, second, and third cams 330, 340, and 350 may be provided inside the housing 310.

The first cam 330 may include a screw hole 332 through which the thread 322 passes. The screw hole 332 may be translated in the first direction A or in the second direction B by rotation of the thread 322 when the height-adjustable screw 320 is rotated in one direction or in the opposite direction.

The first cam 330 may include a first cam surface 331 in contact with the second cam 340.

The second cam 340 may include a second cam surface 341 in contact with the first cam surface 331. When the first cam 330 is moved in the first direction A, the second cam surface 341 may be pressed against the first cam surface 331 to move the second cam 340 in the third direction C.

The adjusting unit 300 may include an elastic member 360, which is disposed between one inner surface of the housing 310 and the opposite surface of the second cam surface 341 in the second cam 340, pressing the second cam 340 in the direction opposite to the third direction C.

Accordingly, the second cam 340 may be moved in the third direction C by the first cam 330, and it may be translated in the direction opposite to the third direction C by the elastic member 360.

The second cam 340 may include a third cam surface 342 come in contact with the third cam 350.

The third cam 350 may include a fourth cam surface 351 come in contact with the third cam surface 342.

The third cam 350 may be moved in the first direction by being pressed against the third surface 342 when the second cam 340 is moved in the third direction C, and it may be translated in the second direction B when the second cam 340 is moved in the direction opposite to the third direction C.

The second cam 340 may include a guide protrusion 343 protruding from the third cam surface 342 to prevent the fourth cam surface 351 from being separated from the third cam surface 342, and the third cam 350 may include a guide rail 352 into which the guide protrusion 343 is inserted.

The guide protrusion 343 may guide the movement of the third cam 350 by the guide rail 352, and at the same time it may prevent the fourth cam surface 351 from being separated from the third cam surface 342.

In other words, when the second cam 340 is moved in the opposite direction to the third direction C, the third cam 350 may maintain its position without moving in the second direction B, and the third cam 350 may be linked with the movement of the second cam 340 in the direction opposite to the third direction C by the guide protrusion 343 and the guide rail 352, and may be moved in the second direction B.

The third cam 350 may include a support surface 353 disposed on a surface opposite to the fourth cam surface 351.

The first PCB 110 may be supported by the support surface 353, and may be linked with the movement of the third cam 350 in the first direction or the second direction B, and may be finely moved in the first direction A or in the second direction B. That is, the first PCB 110 may be bonded to the support surface 353 and be moved in the moving direction of the third cam 350.

The support surface 353 may be provided to come in contact with the opposite surface 112 of the first PCB 110, and may support the first PCB 110.

Particularly, an adhesive layer 40 is disposed on the support surface 353 and the adhesive layer 40 bonds the support surface 353 and the opposite surface 112 to allow the support surface 353 to support the opposite surface 112 of the first PCB 110.

As described above, the adhesive layer 40 may also be disposed on the front surface 210a of the first frame 210. Hereinafter, for convenience of description, the adhesive layer 40 disposed on the support surface 353 is classified as a first adhesive layer 41, and the adhesive layer 40 disposed on the front surface 210a is classified as a second adhesive layer 42.

The adhesive layer 40 is formed of a material including softness and adhesiveness, and may be disposed on the support surface 353 and the front surface 210a in the form of a double-sided adhesive tape or adhesive. The first PCB 110 may be finely moved in the first direction A or the second direction B with respect to the adjusting unit 300 in a state in which the first PCB 110 is bonded to the first frame 210 with the second adhesive layer 42.

At this time, it will be described later, since the adjusting unit 300 moves the first PCB 110 to a fine distance, the second adhesive layer may bond the first PCB 110 or the first frame 210 without being separated from the first PCB 110 or the first frame 210 by the softness of the second adhesive layer 42.

As mentioned above, by the rotation of the height-adjustable screw 320, the three cams 330, 340, and 350 may move in conjunction, accordingly, the support surface 353 supporting the first PCB 110 may be moved in the first direction A or the second direction B.

Since the distance h2 which is substantially moved by the linkage of the three cams 330, 340, and 350 is formed shorter than the distance h1 which may be moved in the first direction A by the height-adjustable screw 320, the first PCB 110 may adjust a fine height of the front and rear directions of the first PCB 110 by the adjusting unit 300.

Particularly, the distance that the support surface 353 moves may be moved by a distance smaller than the pitch of thread 322 of the height-adjustable screw 320 by each inclination of the cam surfaces 331, 341, 342, and 351 formed on the three cams 330, 340, and 350.

In detail, when it is assumed that a inclination angle between the first cam surface 331 and a extending direction of the height-adjustable screw 320 of the second cam surface 341 is 01, and a inclination angle between the third cam surface 342 and a direction perpendicular to the extending direction of the height-adjustable screw 320 of the fourth cam surface 351 is θ2, when the height-adjustable screw 320 is rotated once, the moving distance of the support surface 353 is equal to a value obtained by multiplying the pitch length of the thread 322 by tan θ1 and tan θ2.

In other words, assuming that the moving distance of the support surface 353 is d, d=thread pitch*tan θ1*tan θ2 may be satisfied.

When the height-adjustable screw 320 rotates once, the first cam 330 is moved in the first direction A by the pitch of the thread 232, the second cam 340 may be moved in the third direction C by thread pitch*tan θ1 by the first cam surface 331 and the second cam surface 341.

The third cam 350 may be moved by thread pitch*tan θ1*tan θ2 in the first direction A by the third cam surface 342 and the fourth cam surface 351.

By linked movement of three cams 330, 340, and 350, the height of the support surface 353 may be reduced by a ratio of a tangent value of θ1 and θ2 with respect to the height that may be adjusted in the first direction A by the height-adjustable screw 320.

For example, assuming that the pitch of the thread 322 of the height-adjustable screw 320 is 400 millimeters, θ1 is 10 degrees, and θ2 is 20 degrees, when the height-adjustable screw 320 is rotated once, the distance, at which the first PCB 110 may be moved in the first direction A by the height-adjustable screw 320, is 400 mm, but by the adjusting unit 300, the distance at which the first PCB 110 may be moved in the first direction A is 400*tan 10*tan 20, which is approximately 256 micrometers.

In other words, when the pitch of generally used a screw is 400mm, the adjusting unit 300 may finely move the first PCB 110 by 356 micrometers by one rotation of the screw.

Accordingly, the adjusting unit 300 may adjust the step difference between the plurality of PCBs 100 to within approximately 10 micrometers. Accordingly, the image quality of the display apparatus 1 may be improved.

Also, although not shown in the drawing, the display apparatus 1 may not include the adjusting unit 300, in the process in which the PCB 100 is coupled to the chassis 20, the PCB 100 is coupled to the chassis 20 through the adjusting unit 300, when the combination of the PCB 100 and the chassis 20 is terminated, the adjusting unit 300 may be separated from the display apparatus 1.

Hereinafter, an adjusting unit 300 according to another embodiment of the disclosure will be described. Components other than a pressing member 380 described below are the same as those of the adjusting unit 300 of the above-described embodiment, and thus a redundant description will be omitted.

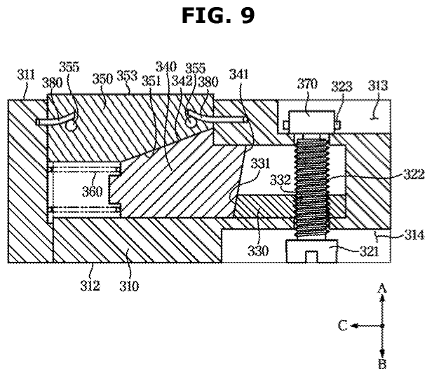

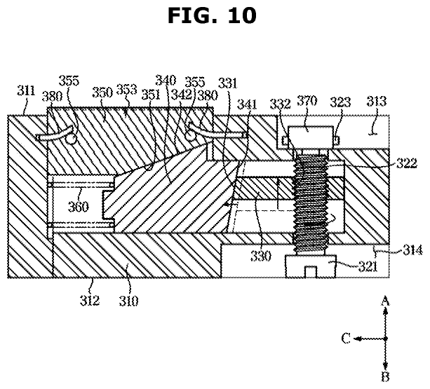

FIG. 9 is a cross-sectional side view illustrating an adjusting unit of a display apparatus according to another embodiment of the disclosure, and FIG. 10 is a side cross-sectional view illustrating an adjusted state of the adjusting unit of the display apparatus according to another embodiment of the disclosure.

The adjusting unit 300 may include a pressing member 380 for pressing the third cam 350 downward to prevent the fourth cam surface 351 from being separated from the third cam surface 342.

The pressing member 380 may guide the movement in the second direction B of the third cam 350 when the second cam 340 is moved in the opposite direction to the third direction C, and at the same time, it may prevent the fourth cam surface 351 from being separated from the third cam surface 342.

In other words, when the second cam 340 is moved in the opposite direction to the third direction C, the third cam 350 may maintain its position without moving in the second direction B, and the third cam 350 may be linked with the movement of the second cam 340 in the direction opposite to the third direction C by the pressing member 380, and may be moved in the second direction B.

One end of the pressing member 380 is coupled to the housing 310 and the other end of the pressing member 380 may be disposed to come in contact with the pressing protrusion 355 provided on the third cam 350 in the vertical direction.

The pressing member 380 may be formed in the same configuration as a plate spring. The pressing member 330 may elastically press the third cam 350 in the second direction B.

Accordingly, after the third cam 350 is moved in the first direction A by the movement of the second cam 340 in the third direction C, when the second cam 340 is moved in the opposite direction to the third direction C again, the third cam 350 may be moved in the second direction B by the pressing of the pressing member 380.

Although a few embodiments of the disclosure have been shown and described, it would be appreciated by those skilled in the art that changes may be made in these embodiments without departing from the principles of the disclosure, the scope of which is defined in the claims.

[Description of Symbols]

| | |
|---|---|
| 1: display apparatus | 100: a plurality of PCBs |
| 110: a first PCB | 200: a plurality of frames |
| 210: a first frame 210 | 300: an adjusting unit |
| 310: a housing | 320: a height-adjustable screw |
| 330: a first cam | 340: a second cam |
| 350: a third cam | 360: an elastic member |
| 370: a screw fixing portion | |

1. A display apparatus comprising:
a printed circuit board (PCB) on which a plurality of light emitting diodes (LEDs) emitting light in a first direction are mounted;
a frame configured to support the PCB in a second direction opposite to the first direction;
a chassis coupled to the frame in the second direction; and
an adjusting unit configured to finely adjust the PCB in the first direction or the second direction,
wherein the adjusting unit includes:
a height-adjustable screw configured to be inserted in the first direction;
a first cam linearly moving in the first direction or the second direction by rotation of the height-adjustable screw;
a second cam interlocking with the first cam so as to linearly move in a third direction that is perpendicular to the first direction and the second direction, or in a direction opposite to the third direction; and
a third cam interlocking with the second cam so as to linearly move in the first direction or the second direction, and configured to come in contact with the PCB.

2. The display apparatus according to claim 1, wherein
the frame includes an insertion hole provided so that the adjusting unit is inserted into the frame, the insertion hole including a first opening formed in the first direction and a second opening formed in the second direction; and
the third cam is provided to come contact with the PCB through the first opening.

3. The display apparatus according to claim 2, wherein
the adjusting device is provided to be coupled to the chassis through the second opening.

4. The display apparatus according to claim 1,
wherein the adjusting device further includes a housing configured to cover the first, second, and third cams; and
the housing includes a first surface including a first cutout portion through which the third cam passes, and a second surface disposed parallel to the first surface and including a second cutout portion through which the height-adjustable screw passes.

5. The display apparatus according to claim 4, wherein
the second surface is provided to be coupled to the chassis, and
the chassis includes an adjustment hole formed at a position corresponding to the height-adjustable screw, and provided to expose the height-adjustable screw from an outside when the second surface is coupled the chassis.

6. The display apparatus according to claim 1, wherein
the first cam includes a first cam surface configured to come in contact with the second cam,
the second cam includes a second cam surface configured to come in contact with the first cam surface, and
the first cam surface and the second cam surface are provided to be inclined with respect to the first direction.

7. The display apparatus according to claim 6, wherein
the second cam includes a third cam surface configured to come in contact with the third cam,
the third cam includes a fourth cam surface configured to come in contact with the third cam surface, and
the third cam surface and the fourth cam surface are provided to be inclined with respect to the third direction.

8. The display apparatus according to claim 6, wherein
the second cam is provided to move in the third direction by being pressed against the first cam surface.

9. The display apparatus according to claim 7, wherein
the third cam is provided to be translated in the first direction and the second direction by being pressed against the third cam surface.

10. The display apparatus according to claim 7, wherein
the second cam further includes a guide protrusion protruding from the third cam surface to prevent the fourth cam surface from being separated from the third cam surface; and
the third cam further includes a guide rail into which the guide protrusion is inserted.

11. The display apparatus according to claim 7, wherein
the adjusting device further includes a pressing member configured to press the third cam toward the second cam to prevent the fourth cam surface from being separated from the third cam surface.

12. The display apparatus according to claim 4, wherein
the adjusting device further includes an elastic member disposed between one inner surface of the housing and the second cam to press the second cam in a direction opposite to the third direction.

13. The display apparatus according to claim 4, wherein
the adjusting device further includes a screw fixing portion that limits movement of the height-adjustable screw in the first direction or the second direction.

14. The display apparatus according to claim 1, wherein
the third cam includes a support surface configured to support the PCB; and
the adjusting device further includes a first adhesive portion configured to bond the PCB to the support surface.

15. The display apparatus according to claim 14, wherein
the frame includes a second adhesive portion configured to bond the frame to the PCB.
